(19) United States
(12) Patent Application Publication
(10) Pub. No.: US 2025/0338670 A1
(43) Pub. Date: Oct. 30, 2025

(54) OPTICAL SENSING STRUCTURE, OPTICAL SENSING FILM AND OPTICAL DISPLAY SYSTEM

(71) Applicant: INDUSTRIAL TECHNOLOGY RESEARCH INSTITUTE, Hsinchu (TW)

(72) Inventors: Ruo-Lan CHANG, New Taipei City (TW); Yu- Hsiang LIU, Chiayi City (TW); Chen-Wei LIN, Hsinchu City (TW); Kung-Ching CHU, Taipei City (TW); Wei-Chung CHEN, Kaohsiung City (TW)

(73) Assignee: INDUSTRIAL TECHNOLOGY RESEARCH INSTITUTE, Hsinchu (TW)

(21) Appl. No.: 18/811,024

(22) Filed: Aug. 21, 2024

(30) Foreign Application Priority Data
Apr. 30, 2024 (TW) 113116097

(51) Int. Cl. H01L 31/0232; H01L 25/04; H01L 31/02; H04N 9/31

(52) U.S. Cl. CPC H10F 77/413; H01L 25/042; H04N 9/3194; H10F 77/933

(57) ABSTRACT

An optical sensing structure includes an optical sensing element and at least one first reflector. The optical sensing element has a sensing surface configured to sense ambient light intensity. The first reflector is located at a side of the optical sensing element. The first reflector has a first front surface located over the sensing surface, a first back surface facing away from the first front surface and a first outer lateral surface located between the first front surface and the first back surface. When a length of the first front surface along a first direction is a_1, a length of the first back surface along the first direction is b_1, and an angle between the first outer lateral surface and the first back surface is θ_1, the following conditions are satisfied: 0<a_1/b_1≤0.6 and 25 degrees≤θ_1≤65 degrees.

### CROSS-REFERENCE TO RELATED APPLICATIONS

This non-provisional application claims priority under 35 U.S.C. § 119 (a) on Patent Application No(s). 113116097 filed in Taiwan on Apr. 30, 2024, the entire contents of which are hereby incorporated by reference.

### TECHNICAL FIELD

The present disclosure relates to an optical sensing structure, an optical sensing film and an optical display system.

### BACKGROUND

With the rapid growth in applications of augmented reality (AR) and mixed reality (MR) in recent years, transparent projection technology able to combine real scenes with digital images has become increasingly popular in the market.

However, some transparent projection films may diffuse the light projected thereon, causing a lack of directionality in the imaging light and thus resulting in blurry images. Moreover, the images on these transparent projection films are vulnerable to ambient light. For example, the contrast of the images on these transparent projection films decreases when exposed to strong ambient light, making the images difficult to be observed and thus reducing their visibility.

### SUMMARY

According to one aspect of the present disclosure, an optical sensing structure includes an optical sensing element and at least one first reflector. The optical sensing element has a sensing surface configured to sense ambient light intensity. The at least one first reflector is located at a side of the optical sensing element. The at least one first reflector has a first front surface, a first back surface and a first outer lateral surface. The first front surface is located over the sensing surface. The first back surface faces away from the first front surface. The first outer lateral surface is located between the first front surface and the first back surface. When a length of the first front surface along a first direction is a_1, a length of the first back surface along the first direction is b_1, and an angle between the first outer lateral surface and the first back surface is θ_1, the following conditions are satisfied:

$$0 < a\_ 1 / b\_ 1 \leq 0.6 and 25 degrees \leq θ \_ 1 \leq 65 degrees .$$

According to another aspect of the present disclosure, an optical sensing film includes a transparent substrate, an optical sensing array and at least one wire. The transparent substrate has a supporting surface. The optical sensing array is disposed to the transparent substrate or on the supporting surface of the transparent substrate. The optical sensing array includes a plurality of optical sensing structures. Each of the plurality of optical sensing structures includes an optical sensing element and at least one first reflector. The optical sensing element is disposed on the supporting surface of the transparent substrate. The optical sensing element has a sensing surface. The sensing surface faces away from the supporting surface and is configured to sense ambient light intensity. The at least one first reflector is located at a side of the optical sensing element. The at least one first reflector has a first front surface, a first back surface and a first outer lateral surface. The first front surface is located over the sensing surface. The first back surface faces away from the first front surface. The first outer lateral surface is located between the first front surface and the first back surface. The at least one wire is disposed to the transparent substrate and electrically connected to the optical sensing elements. When a length of the first front surface along a first direction is a_1, a length of the first back surface along the first direction is b_1, and an angle between the first outer lateral surface and the first back surface is θ_1, the following conditions are satisfied: 0<a_1/b_1<0.6 and 25 degrees≤θ_1≤65 degrees.

According to further another aspect of the present disclosure, an optical display system includes the optical sensing film discussed above, a projector and a controller. The projector faces towards the optical sensing film. The controller is in communication connection with the at least one wire and the projector. The controller is configured to obtain a plurality of intensity values of ambient light sensed by the optical sensing array, and the controller is configured to adjust optical characteristics of projection light emitted from the projector based on the plurality of intensity values.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a cross-sectional schematic view of an optical sensing film according to a first embodiment of the present disclosure;

FIG. 2 is a cross-sectional schematic view of an optical sensing film according to a second embodiment of the present disclosure;

FIG. 3 is a cross-sectional schematic view of an optical sensing film according to a third embodiment of the present disclosure;

FIG. 4 is a cross-sectional schematic view of an optical sensing film according to a fourth embodiment of the present disclosure;

FIG. 5 is a cross-sectional schematic view of an optical sensing film according to a fifth embodiment of the present disclosure;

FIG. 6 is a cross-sectional schematic view of an optical sensing film according to a sixth embodiment of the present disclosure;

FIG. 7 is a cross-sectional schematic view of an optical sensing film according to a seventh embodiment of the present disclosure;

FIG. 8 is a simulation diagram showing an imaging light path performed by the optical sensing film according to one embodiment of the present disclosure;

FIG. 9 is a distribution diagram showing a simulated image location of the imaging light of FIG. 8;

FIG. 10 is a simulation diagram showing an imaging light path performed by the optical sensing film according to another embodiment of the present disclosure;

FIG. 11 is a distribution diagram showing a simulated image location of the imaging light of FIG. 10;

FIG. 12 is a simulation diagram showing an imaging light path performed by a film of a comparative example;

FIG. 13 is a distribution diagram showing a simulated image location of the imaging light of FIG. 12;

FIG. 14 is a cross-sectional schematic view of an optical sensing film according to an eighth embodiment of the present disclosure; and

FIG. 15 is a schematic view of an optical display system according to a ninth embodiment of the present disclosure.

### DETAILED DESCRIPTION

Aspects and advantages of the invention will become apparent from the following detailed descriptions with the accompanying drawings. For purposes of explanation, one or more embodiments are given to provide a thorough understanding of the invention, and which are described in sufficient detail to enable one skilled in the art to practice the described embodiments. It should be understood that the following descriptions are not intended to limit the embodiments to one embodiment. On the contrary, it is intended to cover alternatives, modifications, and equivalents as can be included within the spirit and scope of the described embodiments as defined by the appended claims.

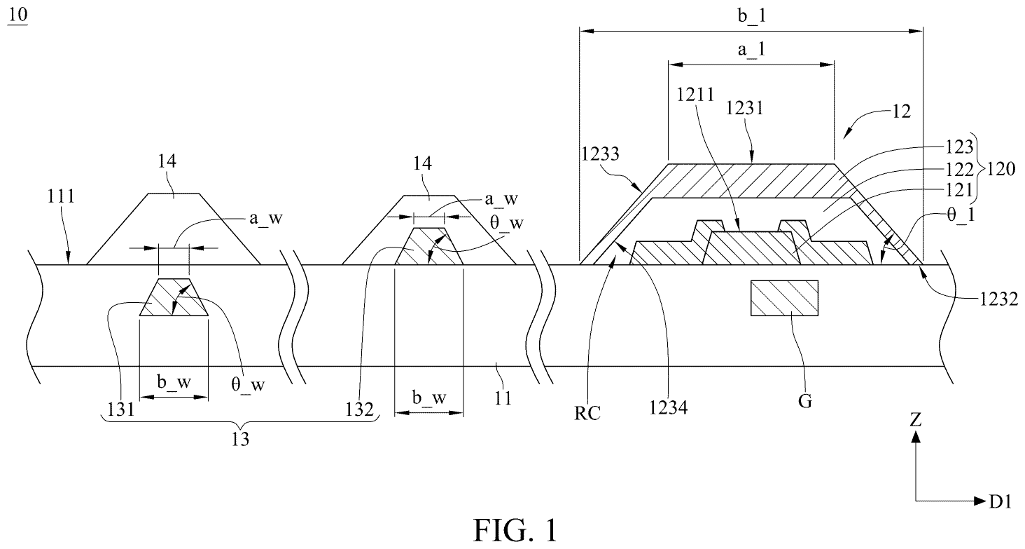

Please refer to FIG. 1, which is a cross-sectional schematic view of an optical sensing film 10 according to a first embodiment of the present disclosure. The optical sensing film 10 includes a transparent substrate 11, an optical sensing array 12 and a wire group 13. The transparent substrate 11 has a supporting surface 111. The optical sensing array 12 and the wire group 13 are disposed to the transparent substrate 11. Please be noted that the optical sensing array 12 and the wire group 13 have small sizes in actual and therefore are not easily observed by naked eyes, such that the optical sensing film 10 is still translucent to the naked eyes in visual.

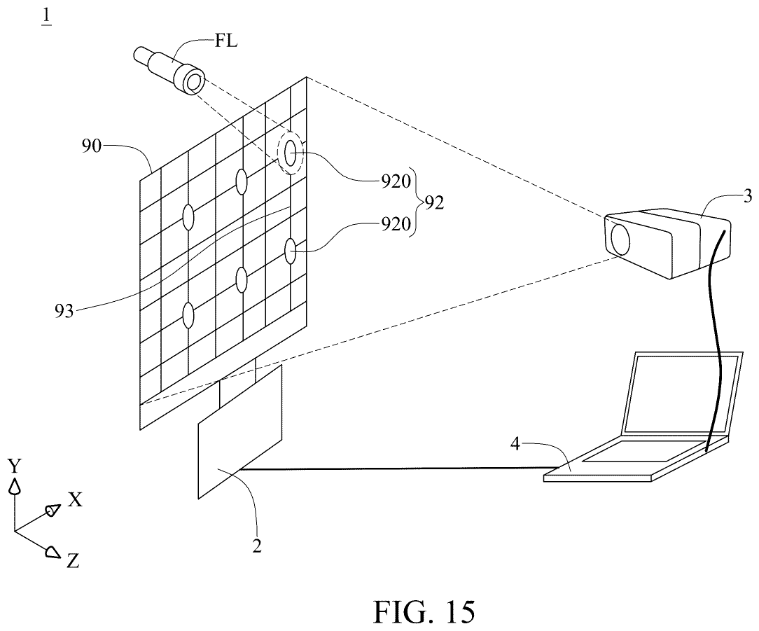

The optical sensing array 12 may include a plurality of optical sensing structures 120. Please refer to FIG. 15 for describing the array arrangement, a plurality of optical sensing structures 920 (corresponding to the optical sensing structures 120) may be, for example, spaced apart from each other and distributed in an optical sensing film 90 (corresponding to the optical sensing film 10) along the X direction and the Y direction so as to form an array. In this embodiment, the optical sensing structures 120 may be similar in structure to one another. For simplicity, only one optical sensing structure 120 is illustrated in FIG. 1.

As shown in FIG. 1, each optical sensing structure 120 may include an optical sensing element 121, a first light guide 122 and a first reflector 123 stacked on the supporting surface 111 of the transparent substrate 11. Please be noted that the transparent substrate 11 may be a simple glass layer or may be integrated by a plurality of translucent layers which are, for example, any combination of an insulation layer, a buffer layer, a barrier layer or a glass layer, and the present disclosure is not limited thereto.

The optical sensing element 121 may include, for example, a thin film transistor (TFT) of an a-Si, LTPS (low temperature poly-silicon), organic, 2D material, or AOS (amorphous oxide semiconductor) type, a diode of a PIN or PN type, or a similar electronic component. The optical sensing element 121 has a sensing surface 1211. The sensing surface 1211 faces away from the supporting surface 111 and is configured to sense ambient light intensity.

The first light guide 122 may be made of organic photoresist materials, PMMA (poly(methyl methacrylate)), epoxy resin or inorganic film materials. The first light guide 122 has characteristics such as, for example, a light refractive index ranging from 1 to 3, a light transmittance greater than or equal to 70%, and a haze less than or equal to 10%. The first light guide 122 is disposed on the optical sensing element 121. The first light guide 122 is located between the optical sensing element 121 and the first reflector 123 and is translucent. In some embodiments of the present disclosure, the first light guide is optional and thus can be omitted based on based on actual requirements. This description of omission of the first light guide may also be applicable in the following embodiments.

The first reflector 123 may be made of reflective materials for reflecting light. The reflective materials may include, for example, aluminum, silver, titanium, molybdenum or an alloy. The first reflector 123 is disposed on the first light guide 122 and thus is located at a side of the optical sensing element 121 away from the supporting surface 111. The first reflector 123 has a first front surface 1231, a first back surface 1232, a first outer lateral surface 1233 and a first inner lateral surface 1234. The first front surface 1231 is located above the sensing surface 1211. The first back surface 1232 faces away from the first front surface 1231 and may be substantially flush with the supporting surface 111. The first outer lateral surface 1233 is located between the first front surface 1231 and the first back surface 1232. The first inner lateral surface 1234 is recessed from the first back surface 1232 towards the first front surface 1231 so as to form a recess RC for accommodating the optical sensing element 121.

According to the structure discussed above, the first inner lateral surface 1234 of the optical sensing structure 120 and the supporting surface 111 of the transparent substrate 11 surround the optical sensing element 121 and the first light guide 122. With this configuration, light incident from a side of the transparent substrate 11 where the optical sensing array 12 is not disposed can pass through the transparent substrate 11 and the first light guide 122 to be reflected off the first reflector 123, and the reflected light can incident onto the sensing surface 1211 of the optical sensing element 121 to enhance optical intensity signals sensed by the optical sensing element 121.

The wire group 13 can be disposed corresponding to the vicinity of the optical sensing array 12. Each wire group 13 may include at least one wire. For example, each wire group 13 in this embodiment includes a first wire 131 and a second wire 132. The first wire 131 and the second wire 132 may be made of metal or alloy capable of reflecting light. The first wire 131 may be disposed in the transparent substrate 11. The second wire 132 may be disposed on the supporting surface 111 of the transparent substrate 11. Every first wire 131 or every second wire 132 may be similar in structure. For simplicity, only one first wire 131 and one second wire 132 are illustrated in FIG. 1.

In one embodiment, taking the TFT of the a-Si type (a-Si TFT) as an example of the optical sensing element 121, the first wire 131 and the second wire 132 can be electrically connected to the optical sensing element 121 through a gate electrode G so as to transmit optical intensity signals sensed by the optical sensing element 121 through the sensing surface 1211.

When a length of the first front surface 1231 along a first direction D1 is a_1, a length of the first back surface 1232 along the first direction D1 is b_1, and an angle between the first outer lateral surface 1233 and the first back surface 1232 is θ_1, the following conditions are satisfied: 0<a_1/b_1<0.6 and 25 degrees≤θ_1<65 degrees. Note that the first direction D1 may be any direction on a plane formed along the X direction and Y direction of FIG. 15.

By satisfying the abovementioned conditions, light incident from a side of the transparent substrate 11 where the optical sensing array 12 is disposed can reach the optical sensing array 12 to be gathered and reflected off the first front surface 1231 and the first outer lateral surface 1233 of the first reflector 123, so that light diffusion can be reduced.

When a width of a side of each of the first wire 131 and the second wire 132 along a normal direction Z of the supporting surface 111 is a_w, a width of another side of each of the first wire 131 and the second wire 132 along the normal direction Z of the supporting surface 111 is b_w, and an angle of a lateral surface of each of the first wire 131 and the second wire 132 with respect to the supporting surface 111 is θ_w, the following conditions are satisfied: 0<a_w/b_w≤0.6 and 25 degrees≤θ_w≤65 degrees. Please be noted that the said side of the first wire 131 having the width a_w refers to the side of the first wire 131 close to the supporting surface 111 in the normal direction Z, the said side of the second wire 132 having the width a_w refers to the side of the second wire 132 away from the supporting surface 111 in the normal direction Z, the said another side of the first wire 131 having the width b_w refers to the side of the first wire 131 away from the supporting surface 111 in the normal direction Z, the said another side of the second wire 132 having the width b_w refers to the side of the second wire 132 close to the supporting surface 111 in the normal direction Z. In one embodiment, the location relationship among the first wire 131, the second wire 132 and the supporting surface 111 may be adjusted based on actual requirements.

By satisfying the abovementioned conditions, light incident from a side of the transparent substrate 11 where the optical sensing array 12 is disposed can reach the wire group 13 to be gathered and reflected off the said side of each of the first wire 131 and the second wire 132, so that light diffusion can be reduced.

The optical sensing film 10 may further include a plurality of second light guides 14. The second light guides 14 may be made of organic photoresist materials, PMMA (poly (methyl methacrylate)), epoxy resin or inorganic film materials. Each second light guide 14 has characteristics such as, for example, a light refractive index ranging from 1 to 3, a light transmittance greater than or equal to 70%, and a haze less than or equal to 10%. The second light guides 14 are disposed on the supporting surface 111 of the transparent substrate 11 and correspond to the first wire 131 and the second wire 132. The second light guides 14 are translucent, so that the path of abovementioned light reflected off the wire group 13 is not affected by the second light guides 14. Please be noted that the shapes of the second light guides 14 illustrated in this embodiment are not intended to restrict the present disclosure. In some embodiments of the present disclosure, each second light guide may alternatively be a patterned layer-structure. Moreover, the second light guide 14 may be formed in the same process as forming the first light guide 122, so that the manufacturing time of the optical sensing film 10 can be saved. In some other embodiments of the present disclosure, the second light guides 14 are optional and thus can be omitted based on actual requirements. This description of omission of the second light guides may also be applicable in the following embodiments.

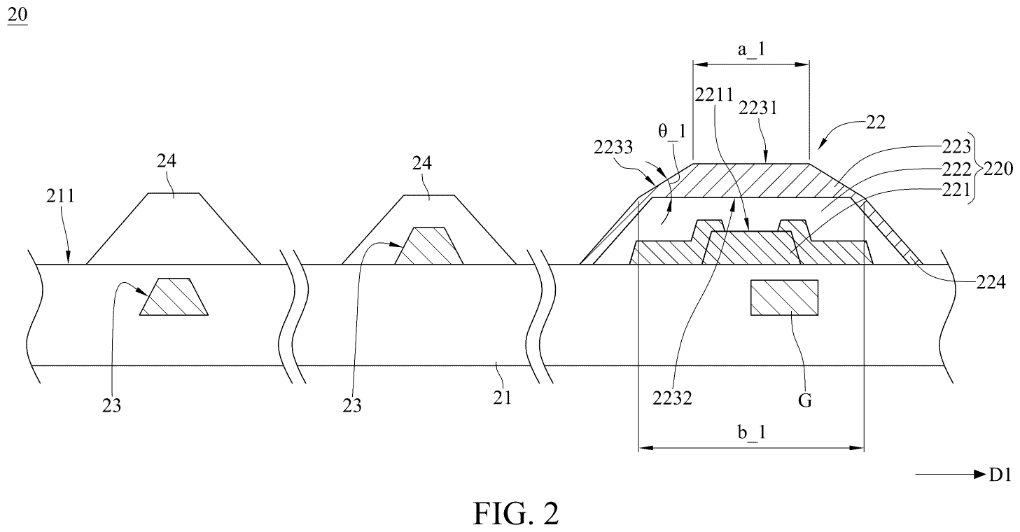

Please refer to FIG. 2, which is a cross-sectional schematic view of an optical sensing film 20 according to a second embodiment of the present disclosure. The optical sensing film 20 includes a transparent substrate 21, an optical sensing array 22, a wire group 23 and a plurality of second light guides 24. The transparent substrate 21 has a supporting surface 211. The optical sensing array 22, the wire group 23 and the second light guides 24 are disposed to the transparent substrate 21. Please be noted that the optical sensing film 20 is translucent to the naked eyes in visual.

The optical sensing array 22 may include a plurality of optical sensing structures 220. Please be noted that the distribution of the optical sensing structures 220 on the supporting surface 211 of the transparent substrate 21 is similar to the distribution of the optical sensing structures 120, and thus related description will not be repeated. Moreover, the optical sensing structures 220 may be similar in structure to one another. For simplicity, one optical sensing structure 220 is illustrated in FIG. 2.

As shown in FIG. 2, each optical sensing structure 220 may include an optical sensing element 221, a first light guide 222 and a first reflector 223 stacked on the supporting surface 211 of the transparent substrate 21, and may further include an extending reflector 224.

The optical sensing element 221 has a sensing surface 2211. The sensing surface 2211 faces away from the supporting surface 211 and is configured to sense ambient light intensity.

The first light guide 222 may be similar in material and characteristic to the first light guide 122 of the first embodiment, and thus related description will not be repeated. The first light guide 222 is disposed on the optical sensing element 221. The first light guide 222 is located between the optical sensing element 221 and the first reflector 223 and is translucent.

The first reflector 223 may be similar in material and characteristic to the first reflector 123 of the first embodiment, and thus related description will not be repeated. The first reflector 223 is disposed on the first light guide 222 and thus is located at a side of the optical sensing element 221 away from the supporting surface 211. The first reflector 223 has a first front surface 2231, a first back surface 2232 and a first outer lateral surface 2233. The first front surface 2231 is located above the sensing surface 2211. The first back surface 2232 faces away from the first front surface 2231 and may be located between the first front surface 2231 and the sensing surface 2211. The first outer lateral surface 2233 is located between the first front surface 2231 and the first back surface 2232.

The extending reflector 224 may be in material similar to or the same as the first reflector 223. The extending reflector 224 is protruded from the first back surface 2232 of the first reflector 223 and is located between the first back surface 2232 of the first reflector 223 and the supporting surface 211 of the transparent substrate 21.

According to the structure discussed above, the extending reflector 224, the first back surface 2232 of the first reflector 223 and the supporting surface 211 of the transparent substrate 21 surround the optical sensing element 221 and the first light guide 222. With this configuration, light incident from a side of the transparent substrate 21 where the optical sensing array 22 is not disposed can pass through the transparent substrate 21 and the first light guide 222 to be reflected off the extending reflector 224 and the first reflector 223, and the reflected light can incident onto the sensing surface 2211 of the optical sensing element 221 to enhance optical intensity signals sensed by the optical sensing element 221.

The wire group 23 and the second light guides 24 are respectively similar in structure and configuration to the wire group 13 and the second light guides 14 of the first embodiment, and thus related description will not be repeated.

When a length of the first front surface 2231 along a first direction D1 is a_1, a length of the first back surface 2232 along the first direction D1 is b_1, and an angle between the first outer lateral surface 2233 and the first back surface 2232 is θ_1, the following conditions are satisfied: 0<a_1/b_1<0.6 and 25 degrees≤θ_1<65 degrees. Note that the first direction D1 may be any direction on a plane formed along the X direction and Y direction of FIG. 15.

By satisfying the abovementioned conditions, light incident from a side of the transparent substrate 21 where the optical sensing array 22 is disposed can reach the optical sensing array 22 to be gathered and reflected off the first reflector 223, so that light diffusion can be reduced.

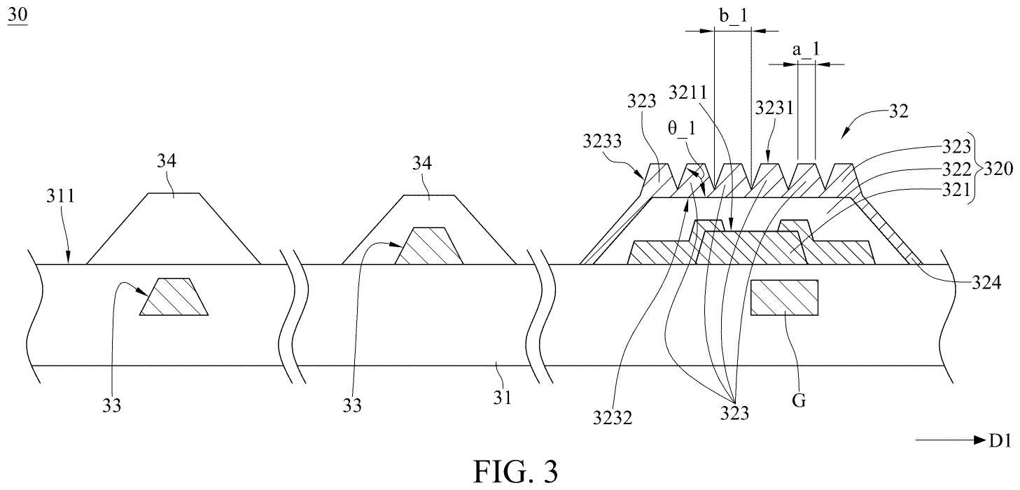

Please refer to FIG. 3, which is a cross-sectional schematic view of an optical sensing film 30 according to a third embodiment of the present disclosure. The optical sensing film 30 includes a transparent substrate 31, an optical sensing array 32, a wire group 33 and a plurality of second light guides 34. The transparent substrate 31 has a supporting surface 311. The optical sensing array 32, the wire group 33 and the second light guides 34 are disposed to the transparent substrate 31. Please be noted that the optical sensing film 30 is translucent to the naked eyes in visual.

The optical sensing array 32 may include a plurality of optical sensing structures 320. Please be noted that the distribution of the optical sensing structures 320 on the supporting surface 311 of the transparent substrate 31 is similar to the distribution of the optical sensing structures 120, and thus related description will not be repeated. Moreover, the optical sensing structures 320 may be similar in structure to one another. For simplicity, one optical sensing structure 320 is illustrated in FIG. 3.

As shown in FIG. 3, each optical sensing structure 320 may include an optical sensing element 321, a first light guide 322 and a plurality of first reflectors 323 stacked on the supporting surface 311 of the transparent substrate 31, and may further include an extending reflector 324. Please be noted that the first reflectors 323 in this embodiment, which are designed as a plurality of micro-structures, are able to increasing the effective reflection ratio, and the micro-structures may be, for example but not limited thereto, manufactured into rectangular or tapered shapes above the first light guide 322 by, for example, multiple masks, grayscale masks or an exposure energy controlling method.

The optical sensing element 321 has a sensing surface 3211. The sensing surface 3211 faces away from the supporting surface 311 and is configured to sense ambient light intensity.

The first light guide 322 may be similar in material and characteristic to the first light guide 122 of the first embodiment, and thus related description will not be repeated. The first light guide 322 is disposed on the optical sensing element 321. The first light guide 322 is located between the optical sensing element 321 and the first reflectors 323 and is translucent.

The first reflectors 323 may be similar in material and characteristic to the first reflector 123 of the first embodiment, and thus related description will not be repeated. The first reflectors 323 may be arranged side by side and disposed on the first light guide 322 and thus are located at a side of the optical sensing element 321 away from the supporting surface 311. Each first reflector 323 has a first front surface 3231, a first back surface 3232 and a first outer lateral surface 3233. The first front surface 3231 is located above the sensing surface 3211. The first back surface 3232 faces away from the first front surface 3231 and may be located between the first front surface 3231 and the sensing surface 3211. The first outer lateral surface 3233 is located between the first front surface 3231 and the first back surface 3232.

The extending reflector 324 may be in material similar to or the same as the first reflectors 323. The extending reflector 324 is protruded from the first back surfaces 3232 of the first reflectors 323 and is located between the first back surfaces 3232 of the first reflectors 323 and the supporting surface 311 of the transparent substrate 31.

According to the structure discussed above, the extending reflector 324, the first back surfaces 3232 of the first reflectors 323 and the supporting surface 311 of the transparent substrate 31 surround the optical sensing element 321 and the first light guide 322. With this configuration, light incident from a side of the transparent substrate 31 where the optical sensing array 32 is not disposed can pass through the transparent substrate 31 and the first light guide 322 to be reflected off the extending reflector 324 and the first reflectors 323, and the reflected light can incident onto the sensing surface 3211 of the optical sensing element 321 to enhance optical intensity signals sensed by the optical sensing element 321.

The wire group 33 and the second light guides 34 are respectively similar in structure and configuration to the wire group 13 and the second light guides 14 of the first embodiment, and thus related description will not be repeated.

When a length of the first front surface 3231 along a first direction D1 is a_1, a length of the first back surface 3232 along the first direction D1 is b_1, and an angle between the first outer lateral surface 3233 and the first back surface 3232 is θ_1, the following conditions are satisfied: 0<a_1/b_1<0.6 and 25 degrees≤θ_1<65 degrees. Note that the first direction D1 may be any direction on a plane formed along the X direction and Y direction of FIG. 15.

By satisfying the abovementioned conditions, light incident from a side of the transparent substrate 31 where the optical sensing array 32 is disposed can reach the optical sensing array 32 to be gathered and reflected off the first reflectors 323, so that light diffusion can be reduced.

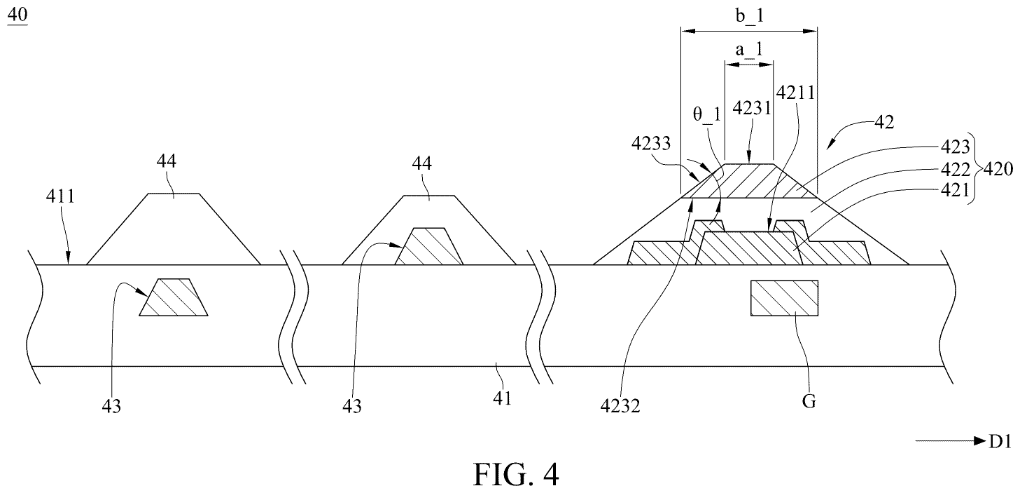

Please refer to FIG. 4, which is a cross-sectional schematic view of an optical sensing film 40 according to a fourth embodiment of the present disclosure. The optical sensing film 40 includes a transparent substrate 41, an optical sensing array 42, a wire group 43 and a plurality of second light guides 44. The transparent substrate 41 has a supporting surface 411. The optical sensing array 42, the wire group 43 and the second light guides 44 are disposed to the transparent substrate 41. Please be noted that the optical sensing film 40 is translucent to the naked eyes in visual.

The optical sensing array 42 may include a plurality of optical sensing structures 420. Please be noted that the distribution of the optical sensing structures 420 on the supporting surface 411 of the transparent substrate 41 is similar to the distribution of the optical sensing structures 120, and thus related description will not be repeated. Moreover, the optical sensing structures 420 may be similar in structure to one another. For simplicity, one optical sensing structure 420 is illustrated in FIG. 4.

As shown in FIG. 4, each optical sensing structure 420 may include an optical sensing element 421, a first light guide 422 and a first reflector 423 stacked on the supporting surface 411 of the transparent substrate 41.

The optical sensing element 421 has a sensing surface 4211. The sensing surface 4211 faces away from the supporting surface 411 and is configured to sense ambient light intensity.

The first light guide 422 may be similar in material and characteristic to the first light guide 122 of the first embodiment, and thus related description will not be repeated. The first light guide 422 is disposed on the optical sensing element 421. The first light guide 422 is located between the optical sensing element 421 and the first reflector 423 and is translucent.

The first reflector 423 may be similar in material and characteristic to the first reflector 123 of the first embodiment, and thus related description will not be repeated. The first reflector 423 is disposed on the first light guide 422 and thus are located at a side of the optical sensing element 421 away from the supporting surface 411. The first reflector 423 has a first front surface 4231, a first back surface 4232 and a first outer lateral surface 4233.

The first front surface 4231 is located above the sensing surface 4211. The first back surface 4232 faces away from the first front surface 4231 and may be located between the first front surface 4231 and the sensing surface 4211. The area of the first back surface 4232 can be greater than or equal to the area of the sensing surface 4211. The first outer lateral surface 4233 is located between the first front surface 4231 and the first back surface 4232.

According to the structure discussed above, the first back surface 4232 of the first reflector 423 is located at a side of the optical sensing element 421 away from the supporting surface 411. With the collaboration with the design in which the first back surface 4232 is greater in area than or equal to the sensing surface 4211, light incident from a side of the transparent substrate 41 where the optical sensing array 42 is not disposed can pass through the transparent substrate 41 and the first light guide 422 to be reflected off the first back surface 4232, and the reflected light can incident onto the sensing surface 4211 of the optical sensing element 421 to enhance optical intensity signals sensed by the optical sensing element 421.

The wire group 43 and the second light guides 44 are respectively similar in structure and configuration to the wire group 13 and the second light guides 14 of the first embodiment, and thus related description will not be repeated.

When a length of the first front surface 4231 along a first direction D1 is a_1, a length of the first back surface 4232 along the first direction D1 is b_1, and an angle between the first outer lateral surface 4233 and the first back surface 4232 is θ_1, the following conditions are satisfied: 0<a_1/b_1<0.6 and 25 degrees≤θ_1≤65 degrees. Note that the first direction D1 may be any direction on a plane formed along the X direction and Y direction of FIG. 15.

By satisfying the abovementioned conditions, light incident from a side of the transparent substrate 41 where the optical sensing array 42 is disposed can reach the optical sensing array 42 to be gathered and reflected off the first reflector 423, so that light diffusion can be reduced.

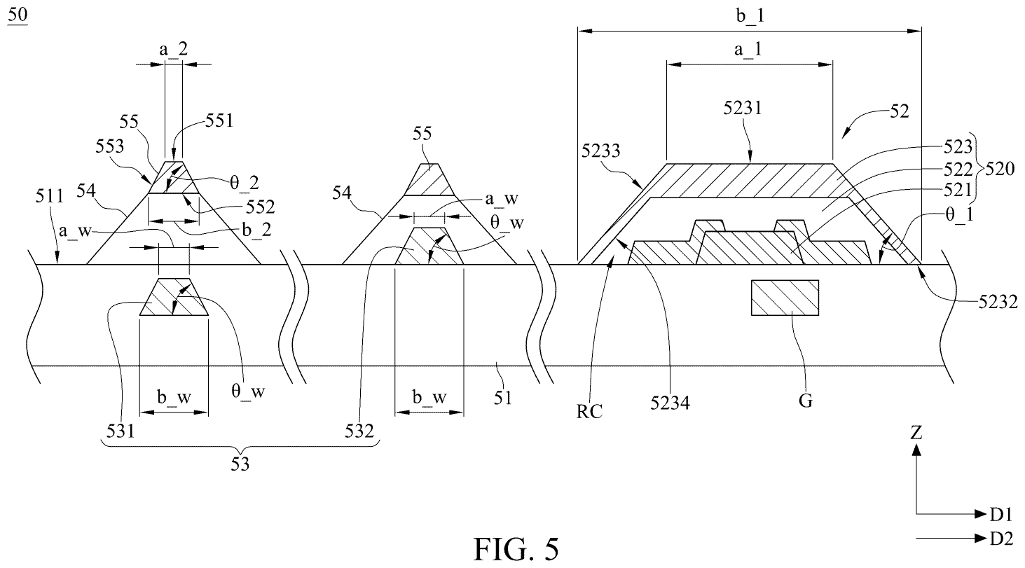

Please refer to FIG. 5, which is a cross-sectional schematic view of an optical sensing film 50 according to a fifth embodiment of the present disclosure. The optical sensing film 50 includes a transparent substrate 51, an optical sensing array 52, a wire group 53, a plurality of second light guides 54 and a plurality of second reflectors 55. The transparent substrate 51 has a supporting surface 511. The optical sensing array 52 and the wire group 53 are disposed to the transparent substrate 51. Please be noted that the optical sensing film 50 is translucent to the naked eyes in visual.

The optical sensing array 52 may include a plurality of optical sensing structures 520. Please be noted that the distribution of the optical sensing structures 520 on the supporting surface 511 of the transparent substrate 51 is similar to the distribution of the optical sensing structures 120, and thus related description will not be repeated. Moreover, the optical sensing structures 520 may be similar in structure to one another. For simplicity, one optical sensing structure 520 is illustrated in FIG. 5.

As shown in FIG. 5, each optical sensing structure 520 may include an optical sensing element 521, a first light guide 522 and a first reflector 523 stacked on the supporting surface 511 of the transparent substrate 51.

The first reflector 523 has a first front surface 5231, a first back surface 5232, a first outer lateral surface 5233 and a first inner lateral surface 5234.

The optical sensing structure 520 is similar in structure and configuration to the optical sensing structure 120 of the first embodiment, and thus some details such as the structure and the configuration of the first light guide 522 and the first reflector 523 will be omitted.

The wire group 53 can be disposed corresponding to the vicinity of the optical sensing array 52. Each wire group 53 may include at least one wire. For example, each wire group 53 includes a first wire 531 and a second wire 532. The first wire 531 and the second wire 532 may be made of metal or alloy capable of reflecting light. The first wire 531 may be disposed in the transparent substrate 51. The second wire 532 may be disposed on the supporting surface 511 of the transparent substrate 51. Every first wire 531 or every second wire 532 may be similar in structure. For simplicity, one first wire 531 and one second wire 532 are illustrated in FIG. 5.

In one embodiment, the first wire 531 and the second wire 532 can be electrically connected to the optical sensing element 521 through a gate electrode G so as to transmit optical intensity signals sensed by the optical sensing element 521.

The second light guides 54 may be similar in material and characteristic to the second light guides 14 of the first embodiment, and thus related description will not be repeated. The second light guides 54 are disposed on the supporting surface 511 of the transparent substrate 51 and correspond to the first wire 531 and the second wire 532. The second light guides 54 are located between the first wire 531 and the second reflectors 55 and between the second wire 532 and the second reflectors 55. The second light guides 54 are translucent.

The second reflectors 55 are disposed on the second light guides 54 and thus are correspondingly located at a side of the first wire 531 and the second wire 532. Each second reflector 55 has a second front surface 551, a second back surface 552 and a second outer lateral surface 553. The second front surface 551 is located at a side of the second reflector 55 away from the supporting surface 511. The second back surface 552 faces away from the second front surface 551 and may be located between the second front surface 551 and the first wire 531 and between the second front surface 551 and the second wire 532. The second outer lateral surface 553 is located between the second front surface 551 and the second back surface 552. Moreover, the second reflectors 55 may be formed in the same process as forming the first reflector 523, so that the manufacturing time of the optical sensing film 50 can be saved.

When a length of the first front surface 5231 along a first direction D1 is a_1, a length of the first back surface 5232 along the first direction D1 is b_1, and an angle between the first outer lateral surface 5233 and the first back surface 5232 is θ_1, the following conditions are satisfied: 0<a_1/b_1≤0.6 and 25 degrees≤θ_1≤65 degrees. Note that the first direction D1 may be any direction on a plane formed along the X direction and Y direction of FIG. 15.

When a length of each second front surface 551 along a second direction D2 is a_2, a length of each second back surface 552 along the second direction D2 is b_2, and an angle between one second outer lateral surface 553 and one second back surface 552 is θ_2, the following conditions are satisfied: 0<a_2/b_2≤0.6 and 25 degrees≤θ_2≤65 degrees. Note that the second direction D2 may be any direction on a plane formed along the X direction and Y direction of FIG. 15, and may be the same direction as the first direction, as shown in FIG. 5.

By satisfying the abovementioned conditions, light incident from a side of the transparent substrate 51 where the optical sensing array 52 is disposed can reach the optical sensing array 52 and the second reflectors 55 to be gathered and reflected off the first reflector 523 and the second reflectors 55, so that light diffusion can be reduced.

When a width of a side of each of the first wire 531 and the second wire 532 along a normal direction Z of the supporting surface 511 is a_w, a width of another side of each of the first wire 531 and the second wire 532 along the normal direction Z of the supporting surface 511 is b_w, and an angle of a lateral surface of each of the first wire 531 and the second wire 532 with respect to the supporting surface 511 is θ_w, the following conditions are satisfied: 0<a_w/b_w≤0.6 and 25 degrees≤θ_w≤65 degrees.

By satisfying the abovementioned conditions, light incident from a side of the transparent substrate 51 where the optical sensing array 52 is disposed can reach the wire group 53 to be reflected off the said side of each of the first wire 531 and the second wire 532, so that light diffusion can be reduced.

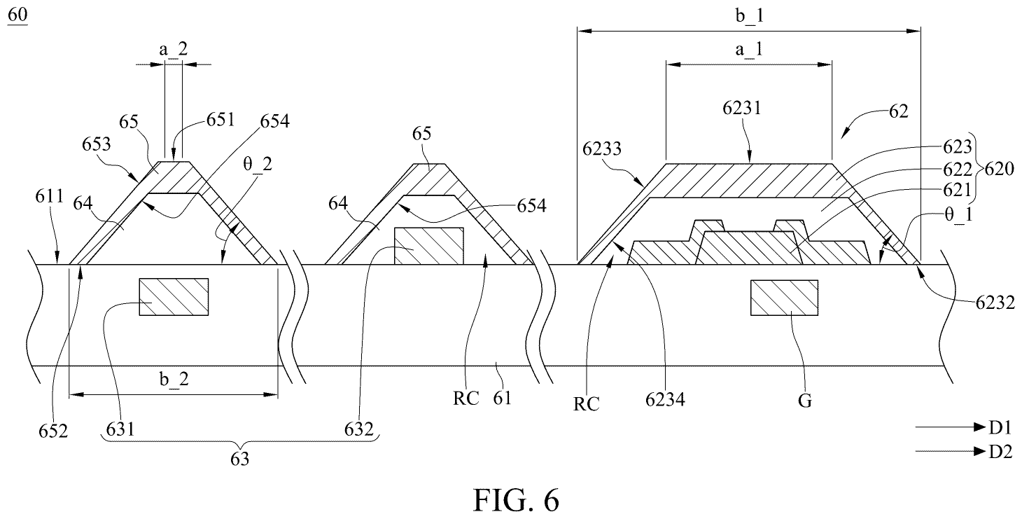

Please refer to FIG. 6, which is a cross-sectional schematic view of an optical sensing film 60 according to a sixth embodiment of the present disclosure. The optical sensing film 60 includes a transparent substrate 61, an optical sensing array 62, a wire group 63, a plurality of second light guides 64 and a plurality of second reflectors 65. The transparent substrate 61 has a supporting surface 611. The optical sensing array 62 and the wire group 63 are disposed to the transparent substrate 61. Please be noted that the optical sensing film 60 is translucent to the naked eyes in visual.

The optical sensing array 62 may include a plurality of optical sensing structures 620. Please be noted that the distribution of the optical sensing structures 620 on the supporting surface 611 of the transparent substrate 61 is similar to the distribution of the optical sensing structures 120, and thus related description will not be repeated. Moreover, the optical sensing structures 620 may be similar in structure to one another. For simplicity, one optical sensing structure 620 is illustrated in FIG. 6.

As shown in FIG. 6, each optical sensing structure 620 may include an optical sensing element 621, a first light guide 622 and a first reflector 623 stacked on the supporting surface 611 of the transparent substrate 61.

The first reflector 623 has a first front surface 6231, a first back surface 6232, a first outer lateral surface 6233 and a first inner lateral surface 6234.

The optical sensing structure 620 is similar in structure and configuration to the optical sensing structure 120 of the first embodiment, and thus some details such as the structure and the configuration of the first light guide 622 and the first reflector 623 will be omitted.

The wire group 63 can be disposed corresponding to the vicinity of the optical sensing array 62. Each wire group 63 may include at least one wire. For example, each wire group 63 includes a first wire 631 and a second wire 632. The first wire 631 and the second wire 632 may be made of metal or alloy capable of reflecting light. The first wire 631 may be disposed in the transparent substrate 61. The second wire 632 may be disposed on the supporting surface 611 of the transparent substrate 61. Every first wire 631 or every second wire 632 may be similar in structure. For simplicity, one first wire 631 and one second wire 632 are illustrated in FIG. 6.

In one embodiment, the first wire 631 and the second wire 632 can be electrically connected to the optical sensing element 621 through a gate electrode G so as to transmit optical intensity signals sensed by the optical sensing element 621.

The second light guides 64 may be similar in material and characteristic to the second light guides 14 of the first embodiment, and thus related description will not be repeated. The second light guides 64 are disposed on the supporting surface 611 of the transparent substrate 61 and correspond to the first wire 631 and the second wire 632. The second light guides 64 are located between the first wire 631 and the second reflectors 65 and between the second wire 632 and the second reflectors 65. The second light guides 64 are translucent.

The second reflectors 65 are disposed on the second light guides 64 and thus are correspondingly located at a side of the first wire 631 and the second wire 632. Each second reflector 65 has a second front surface 651, a second back surface 652, a second outer lateral surface 653 and a second inner lateral surface 654. The second front surface 651 is located at a side of the second reflector 65 away from the supporting surface 611. The second back surface 652 faces away from the second front surface 651 and may be substantially flush with the supporting surface 611. The second outer lateral surface 653 is located between the second front surface 651 and the second back surface 652. The second inner lateral surface 654 is recessed from the second back surface 652 towards the second front surface 651 so as to form a recess RC for accommodating the second wire 632.

When a length of the first front surface 6231 along a first direction D1 is a_1, a length of the first back surface 6232 along the first direction D1 is b_1, and an angle between the first outer lateral surface 6233 and the first back surface 6232 is θ_1, the following conditions are satisfied: 0<a_1/b_1≤0.6 and 25 degrees≤θ_1<65 degrees. Note that the first direction D1 may be any direction on a plane formed along the X direction and Y direction of FIG. 15.

When a length of each second front surface 651 along a second direction D2 is a_2, a length of each second back surface 652 along the second direction D2 is b_2, and an angle between one second outer lateral surface 653 and one second back surface 652 is θ_2, the following conditions are satisfied: 0<a_2/b_2≤0.6 and 25 degrees≤θ_2≤65 degrees. Note that the second direction D2 may be any direction on a plane formed along the X direction and Y direction of FIG. 15, and may be the same direction as the first direction, as shown in FIG. 6.

By satisfying the abovementioned conditions, light incident from a side of the transparent substrate 61 where the optical sensing array 62 is disposed can reach the first reflector 623 and the second reflectors 65 to be reflected off the first reflector 623 and the second reflectors 65, so that light diffusion can be reduced.

Please be noted that the second reflector 65 is designed to have the second inner lateral surface 654 facing towards the wire group 63, so that the shapes of the first wire 631 and the second wire 632 may not be presented as that of the first wire 531 and the second wire 532 of the fifth embodiment. However, the present disclosure is not limited thereto. In some embodiments of the present disclosure, even the second reflector is designed to have the second inner lateral surface facing towards the wire group, the first wire and the second wire may have the shapes similar to that of the first wire 531 and the second wire 532 of the fifth embodiment.

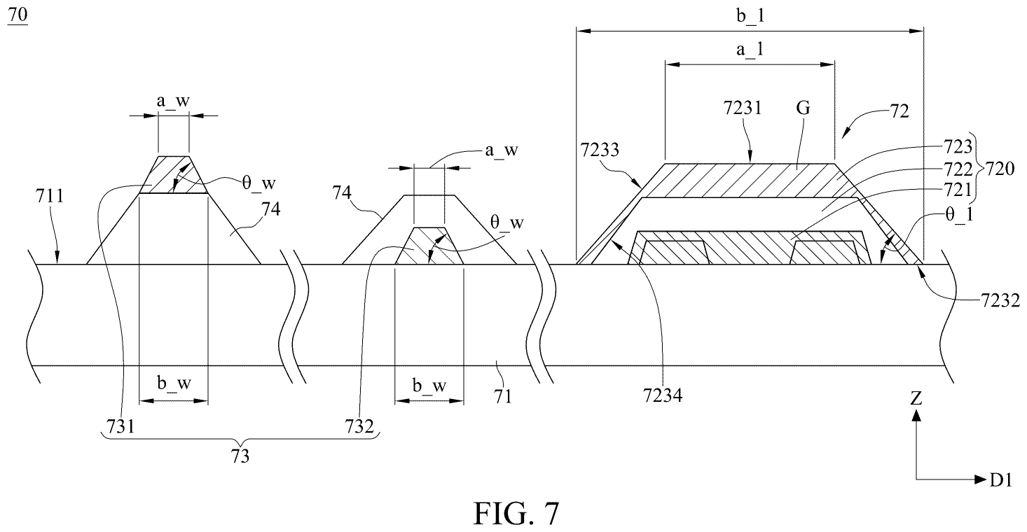

Please refer to FIG. 7, which is a cross-sectional schematic view of an optical sensing film 70 according to a seventh embodiment of the present disclosure. The optical sensing film 70 includes a transparent substrate 71, an optical sensing array 72, a wire group 73 and a plurality of second light guides 74. The transparent substrate 71 has a supporting surface 711. The optical sensing array 72 and the wire group 73 are disposed to the transparent substrate 71. Please be noted that the optical sensing film 70 is translucent to the naked eyes in visual.

The optical sensing array 72 may include a plurality of optical sensing structures 720. Please be noted that the distribution of the optical sensing structures 720 on the supporting surface 711 of the transparent substrate 71 is similar to the distribution of the optical sensing structures 120, and thus related description will not be repeated. Moreover, the optical sensing structures 720 may be similar in structure to one another. For simplicity, one optical sensing structure 720 is illustrated in FIG. 7.

As shown in FIG. 7, each optical sensing structure 720 may include an optical sensing element 721, a first light guide 722 and a first reflector 723 stacked on the supporting surface 711 of the transparent substrate 71.

The first reflector 723 has a first front surface 7231, a first back surface 7232, a first outer lateral surface 7233 and a first inner lateral surface 7234. Moreover, a gate electrode G may be served as the first reflector 723 to further have the function of the first reflector 723. As a result, the gate electrode G is disposed at a side of the optical sensing element 721, which is different from the gate electrode G of the first embodiment.

The optical sensing structure 720 is similar in structure and configuration to the optical sensing structure 120 of the first embodiment, and thus some details such as the structure and the configuration of the first light guide 722 and the first reflector 723 will be omitted.

The wire group 73 can be disposed corresponding to the vicinity of the optical sensing array 72. Each wire group 73 may include at least one wire. For example, each wire group 73 includes a first wire 731 and a second wire 732. The first wire 731 and the second wire 732 may be made of metal or alloy capable of reflecting light. The first wire 731 may be disposed at a side of the transparent substrate 71 and located on one of the second light guides 74. The second wire 732 may be disposed on the supporting surface 711 of the transparent substrate 71. Every first wire 731 or every second wire 732 may be similar in structure. For simplicity, one first wire 731 and one second wire 732 are illustrated in FIG. 7.

In one embodiment, the first wire 731 and the second wire 732 can be electrically connected to the optical sensing element 721 through the gate electrode G with the function of the first reflector 723 so as to transmit optical intensity signals sensed by the optical sensing element 721.

The second light guides 74 may be similar in material and characteristic to the second light guides 14 of the first embodiment, and thus related description will not be repeated. The second light guides 74 are disposed on the supporting surface 711 of the transparent substrate 71 and correspond to the first wire 731 and the second wire 732. The second light guides 74 are located between the first wire 731 and the transparent substrate 71 and on the supporting surface 711 of the transparent substrate 71. The second light guides 74 are translucent.

When a length of the first front surface 7231 along a first direction D1 is a_1, a length of the first back surface 7232 along the first direction D1 is b_1, and an angle between the first outer lateral surface 7233 and the first back surface 7232 is θ_1, the following conditions are satisfied: 0<a_1/b_1≤0.6 and 25 degrees≤θ_1≤65 degrees. Note that the first direction D1 may be any direction on a plane formed along the X direction and Y direction of FIG. 15.

When a width of a side of each of the first wire 731 and the second wire 732 along a normal direction Z of the supporting surface 711 is a_w, a width of another side of each of the first wire 731 and the second wire 732 along the normal direction Z of the supporting surface 711 is b_w, and an angle of a lateral surface of each of the first wire 731 and the second wire 732 with respect to the supporting surface 711 is θ_w, the following conditions are satisfied: 0<a_w/b_w≤0.6 and 25 degrees≤θ_w≤65 degrees.

By satisfying the abovementioned conditions, light incident from a side of the transparent substrate 71 where the optical sensing array 72 is disposed can reach the optical sensing array 72 and/or the wire group 73 to be reflected off the first reflector 723, the first wire 731 and/or the second wire 732, so that light diffusion can be reduced.

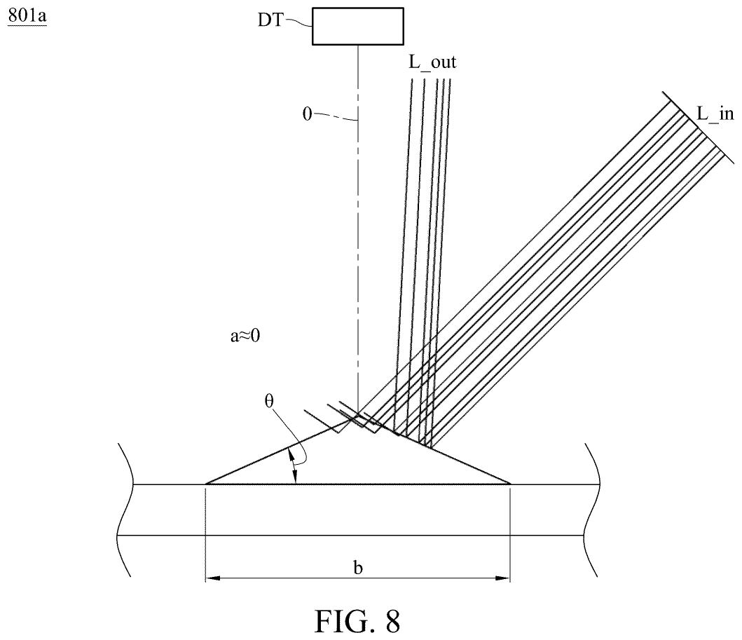

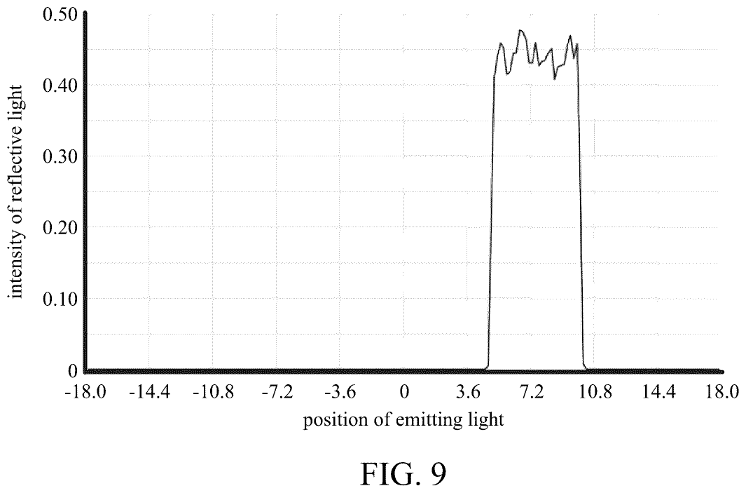

Then, please refer to FIG. 8 to FIG. 9, where FIG. 8 is a simulation diagram showing an imaging light path performed by the optical sensing film 801a according to one embodiment of the present disclosure, and FIG. 9 is a distribution diagram showing a simulated image location of the imaging light of FIG. 8.

The structure illustrated in FIG. 8 may be an optical sensing structure, a wire group or a second reflector of an optical sensing film 801a. For clearly showing the simulation of the imaging light path, contours of the structure are illustrated with other details of the structure as being omitted.

The structure illustrated in FIG. 8 satisfies the following conditions: a/b as being greater than 0 and θ=41.6 degrees, wherein “a” may refer to a_1, a_2 or a_w as mentioned in the above, “b” may refer to b_1, b_2 or b_w as mentioned in the above, and “0” may refer to θ_1, θ_2 or θ_w as mentioned in the above. Please be noted that even if the structure in FIG. 8 is manufactured with a sharp end, “a” actually has a certain length in size. Therefore, a/b would be greater than 0 instead of equal to 0.

The line segment labeled as 0 in FIG. 8 may be in parallel with the normal direction Z as mentioned in the above, which is defined by, for example, the center of a detector DT. As shown in FIG. 8, incident light L_in is reflected to be emitting light L_out. The emitting light L_out is located in a right-side area of the line segment labeled as 0. Correspondingly, in the distribution diagram FIG. 9 showing the simulated image location, the right-side area of the line segment labeled as 0 in FIG. 8 corresponds to a positive-value area of X-axis in FIG. 9. Light in the right-side area is defined as effectively reflective light, which means the reflected light (emitting light L_out) can enter into an effective visible area of a human eye with less light diffusion. When orthogonally observing the optical sensing film 801a, a relatively large amount of emitting light L_out can be received, and an image with relatively good quality can be experienced.

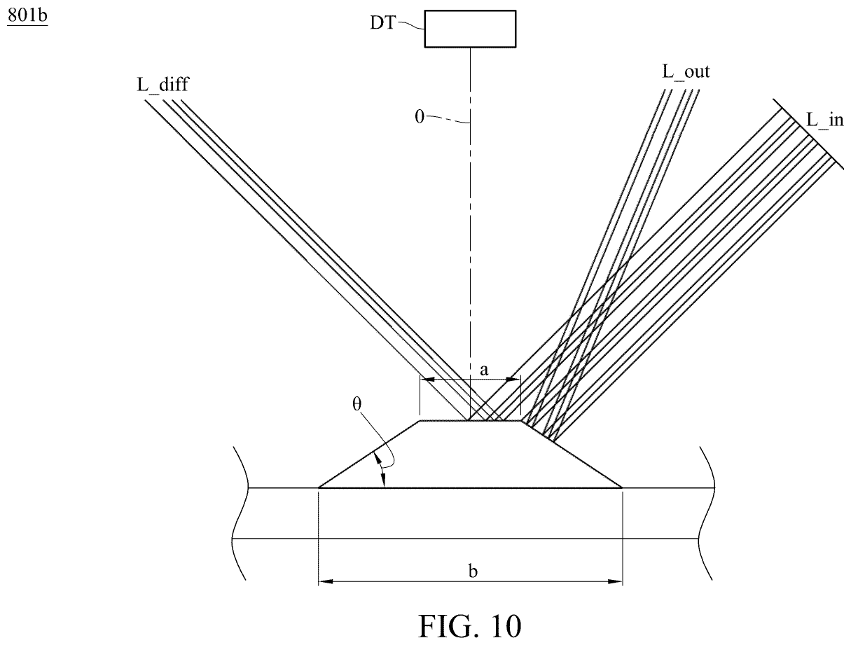

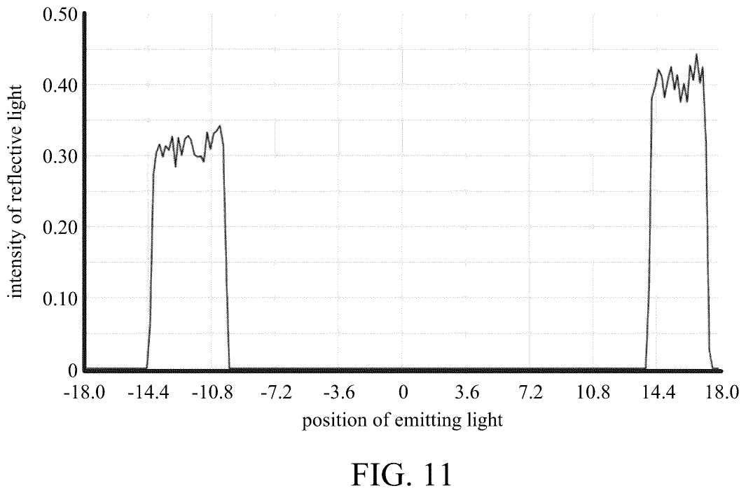

Then, please refer to FIG. 10 to FIG. 11, where FIG. 10 is a simulation diagram showing an imaging light path performed by the optical sensing film 801b according to another embodiment of the present disclosure, and FIG. 11 is a distribution diagram showing a simulated image location of the imaging light of FIG. 10.

The structure illustrated in FIG. 10 may be an optical sensing structure, a wire group or a second reflector of an optical sensing film 801b. For clearly showing the simulation of the imaging light path, contours of the structure are illustrated with other details of the structure as being omitted.

The structure illustrated in FIG. 10 satisfies the following conditions: a/b=0.33 and 0=53.13 degrees, wherein “a” may refer to a_1, a_2 or a_w as mentioned in the above, “b” may refer to b_1, b_2 or b_w as mentioned in the above, and “0” may refer to θ_1, θ_2 or θ_w as mentioned in the above.

The line segment labeled as 0 in FIG. 10 may be in parallel with the normal direction Z as mentioned in the above, which is defined by, for example, the center of a detector DT. As shown in FIG. 10, incident light L_in is reflected to be emitting light L_out and diffusion light L_diff, where the emitting light L_out is located in a right-side area of the line segment labeled as 0. Correspondingly, in the distribution diagram FIG. 11 showing the simulated image location, the right-side area of the line segment labeled as 0 in FIG. 10 corresponds to a positive-value area of X-axis in FIG. 11. Light in the right-side area is defined as effectively reflective light and is visible to a human eye. The diffusion light L_diff is located in the left-side area of the line segment labeled as 0. Similarly, in the distribution diagram FIG. 11 showing the simulated image location, the left-side area of the line segment labeled as 0 in FIG. 10 corresponds to a negative-value area of X-axis in FIG. 11. Light in the left-side area is defined as diffusion light and is hard to be seen by human eyes. As shown in FIG. 11, the total amount of diffusion light L_diff is relatively small and is still far from forming serious diffusion. When orthogonally observing the optical sensing film 801b, a sufficient amount of emitting light L_out can still be received, and a sufficiently clear image can still be experienced.

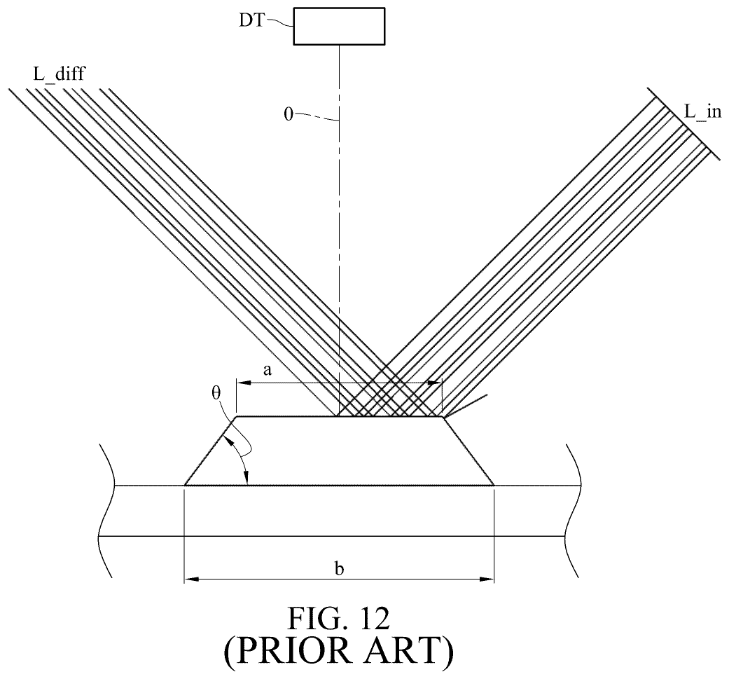

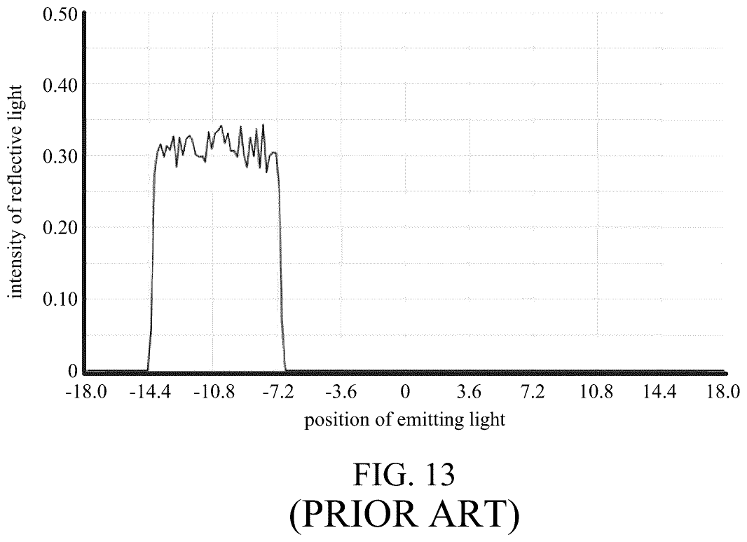

Then, please refer to FIG. 12 to FIG. 13, where FIG. 12 is a simulation diagram showing an imaging light path performed by a film of a comparative example, and FIG. 13 is a distribution diagram showing a simulated image location of the imaging light of FIG. 12.

The structure illustrated in FIG. 12 may be a film with small structures which does not belong to the present disclosure, with the following conditions being satisfied: a/b=0.67 and θ=69.4 degrees, wherein “a” may be realized as similar to a_1, a_2 or a_w as mentioned in the above, “b” may be realized as similar to b_1, b_2 or b_w as mentioned in the above, and “θ” may be realized as similar to θ_1, θ_2 or θ_w as mentioned in the above.

The line segment labeled as 0 in FIG. 12 may be in parallel with the normal direction of the film, which is defined by, for example, the center of a detector DT. As shown in FIG. 12, plenty of incident light L_in is reflected to be diffusion light L_diff. The diffusion light L_diff is located in the left-side area of the line segment labeled as 0. Correspondingly, in the distribution diagram FIG. 13 showing the simulated image location, the left-side area of the line segment labeled as 0 in FIG. 12 corresponds to a negative-value area of X-axis in FIG. 13. Light in the left-side area is defined as diffusion light and is hard to be seen by human eyes, causing poor image. When orthogonally observing the film not belonging to the present disclosure, sufficient light is hardly received for forming a clear image.

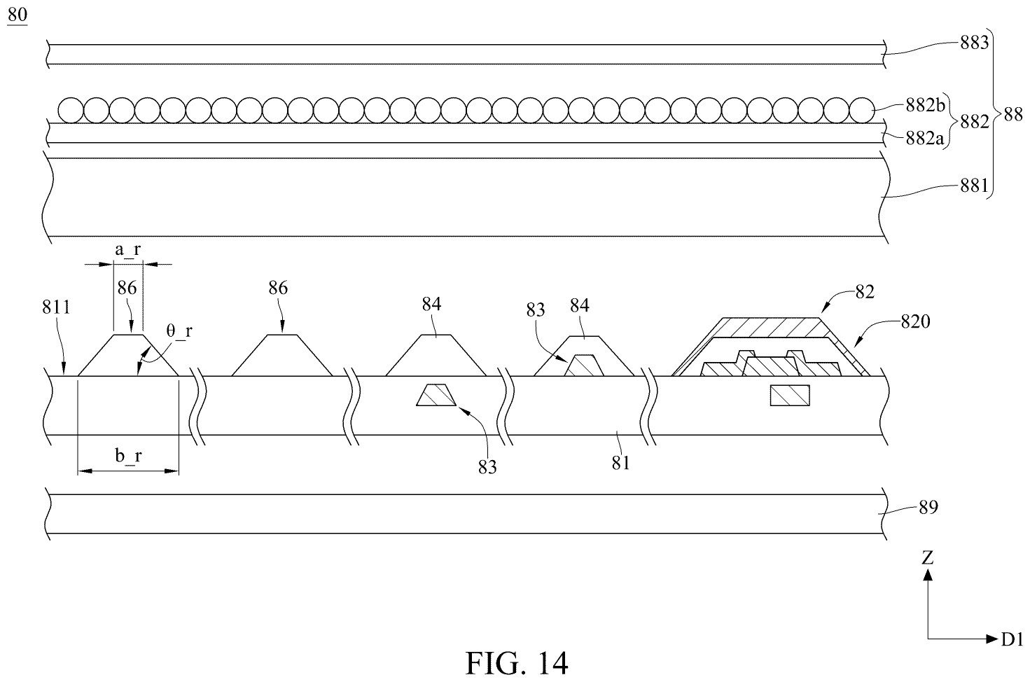

Please refer to FIG. 14, which is a cross-sectional schematic view of an optical sensing film 80 according to an eighth embodiment of the present disclosure.

The optical sensing film 80 includes a transparent substrate 81, an optical sensing array 82, a wire group 83 and second light guides 84. Please be noted that the transparent substrate 81, the optical sensing array 82, the wire group 83 and the second light guides 84 can be respectively similar to any one of the transparent substrates 11 to 71, any one of the optical sensing arrays 12 to 72, any one of the wire groups 13 to 73 and any one of the second light guides 14 to 74 in the abovementioned embodiments. FIG. 14 is illustrated as being at least partially similar to the elements of the first embodiment, but the present disclosure is not limited thereto. Noted that the optical sensing array 82 in FIG. 14 is exemplarily illustrated with one optical sensing structure 820, but the quantity of the optical sensing structure 820 is not limited thereto. In some embodiments of the present disclosure, the quantity of the optical sensing structure may be plural.

In this embodiment, the optical sensing film 80 may further include a plurality of layer structures 88 that are translucent and are disposed at a side of the optical sensing structure 820 away from the transparent substrate 81. The layer structures 88 may include, for example, an optical clear adhesive (OCA) layer 881, a diffusion membrane layer 882 and/or a protection membrane 883. The OCA layer 881 can enable the adhesion of the layer structures 88 onto the optical sensing structure 820 and the second light guides 84. The diffusion membrane layer 882 has a plate 882a and a plurality of diffusion particles 882b. The plate 882a is adhered to the OCA layer 881. The plate 882a is made of, for example, polyethylene terephthalate (PET). The diffusion particles 882b are disposed on the plate 882a. The diffusion particles 882b can further reflect light to form diffuse reflection for leveling the intensity distribution of a projection light source. The protection membrane 883 is disposed at a side of the diffusion particles 882b away from the OCA layer 881. The protection membrane 883 can protect the stacked structure in other layers of the optical sensing film 80.

The optical sensing film 80 may further include an adhesion layer 89 (e.g., an electrostatic film). The adhesion layer 89 is translucent and is disposed at a side of the transparent substrate 81 where the optical sensing structure 820 and the second light guides 84 are not disposed. The adhesion layer 89 can enable the adhesion of the optical sensing film 80 onto any element to be used (e.g., a windscreen/windshield of a car) for providing users with related information display.

In this or another embodiment of the present disclosure, the optical sensing film 80 may further include a plurality of reflection structures 86 disposed on a supporting surface 811 of the transparent substrate 81 and may be disposed, for example, at the same side as the optical sensing structure 820.

When a length of a side of the reflection structures 86 away from the transparent substrate 81 along the first direction D1 is a_r, a length of a side of the reflection structures 86 close to the transparent substrate 81 along the first direction D1 is b_r, and an angle of a lateral surface of the reflection structures 86 with respect to the supporting surface 811 is θ_r, the following conditions are satisfied: 0<a_r/b_r≤0.6; and 25 degrees≤θ_r≤65 degrees.

By satisfying the abovementioned conditions, the reflection structures 86 able to gather and reflect light can be disposed on the position where the optical sensing array 82, the wire group 83 and the second light guides 84 are not arranged, which can further reduce light diffusion.

Please be noted that in the premise that the arrangement quantity of the reflection structures 86 is sufficient, each wire of the wire group 83 may alternatively have a simple rectangular shape (e.g., the shape of the first wire 631 or the second wire 632 of the sixth embodiment). The present disclosure is not limited thereto.

Please refer to FIG. 15, which is a schematic view of an optical display system 1 according to a ninth embodiment of the present disclosure. The optical display system 1 may include an optical sensing film 90, a driver 2, a projector 3 and a controller 4.

The optical sensing film 90 may be any one of the optical sensing films 10 to 80 in the abovementioned first through eighth embodiments. In this embodiment, the optical sensing film 90 may be, for example, the optical sensing film 10 of the first embodiment.

The driver 2 may be in communication connection with a wire group 93 of the optical sensing film 90. Please be noted that the wire group 93 can be similar to any one of the wire groups 13 to 83 in the abovementioned embodiments, and therefore will not be repeated. The projector 3 faces towards the optical sensing film 90 so as to project light for imaging onto the optical sensing film 90. The controller 4 may be, for example, a computer. The controller 4 is in communication connection with the projector 3, and is in communication connection with the wire group 93 of the optical sensing film 90 through the driver 2. Please be noted that the driver 2 is optional, and therefore the controller 4 may alternatively in direct communication connection with the wire group 93 of the optical sensing film 90.

The controller 4 is configured to obtain a plurality of intensity values of ambient light sensed by a plurality of optical sensing structures 920 of the optical sensing array 92 through the wire group 93. Please be noted that the optical sensing array 92 can be similar to any one of the optical sensing arrays 12 to 82 in the abovementioned embodiments, and therefore will not be repeated. The controller 4 can adjust optical characteristics of projection light emitted from the projector 3 based on the intensity values (e.g., the intensity or the contrast of light). An LCR, for example, can be adjusted within the most suitable range to general human eyes, wherein the LCR=bright luminance/dark luminance, and the range 1.5≤LCR≤1.7 provides the best image contrast for human eyes.

For example, the optical sensing film 90, as shown in FIG. 15, is partially illuminated from the rear side by a flashlight FL. The optical sensing structure(s) 920 located in the illuminated area can sense a relatively high intensity value of light. The controller 4 can instruct the projector 3 to correspondingly emit projection light with relatively high brightness onto the illuminated area based on the relatively high intensity value of light, such that a clear image can be seen by a user who is observing the optical sensing film 90 from the same side as the projector 3. In some embodiments of the present disclosure, the controller may, for example, adjust the contrast or the colors of the projection light.

Also, with the structural arrangement of the optical sensing film 90, the optical intensity signals sensed by the optical sensing structures 920 can be enhanced, such that the controller 4 can obtain a relatively accurate intensity value and therefore can provide a relatively accurate control instruction.

Please be noted that the circular shapes of the optical sensing structures 920 observed along the normal direction Z in FIG. 15 are not intended to restrict the present disclosure. In some embodiments of the present disclosure, the optical sensing structures observed along an observation direction may each have an elliptical, oval, rectangular, triangular, polygonal or irregular shape.

According to the optical sensing structure, the optical sensing film and the optical display system discussed above, light incident from a side of the transparent substrate where the optical sensing array is disposed can be reflected off the optical sensing film when reaching the optical sensing film, which can reduce diffusion and provide a relatively large amount of emitting light so as to improve image quality.

Further, the optical display system can adaptively adjust optical characteristics of projection light emitted by the projector based on the intensity values of ambient light sensed by the optical sensing structure, such that clear image can be obtained on the optical sensing film. With the structural arrangement of the optical sensing structure, the optical intensity signals sensed by the optical sensing structure can be enhanced, such that the controller can obtain a relatively accurate intensity value and therefore can provide a relatively accurate control instruction.

The communication connection mentioned in the present disclosure refers to a connection manner that two components are able to exchange signals with each other by, for example, wireless transmission.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. An optical sensing structure, comprising:
an optical sensing element, having a sensing surface configured to sense ambient light intensity; and
at least one first reflector, located at a side of the optical sensing element, wherein the at least one first reflector has a first front surface, a first back surface and a first outer lateral surface, the first front surface is located over the sensing surface, the first back surface faces away from the first front surface, and the first outer lateral surface is located between the first front surface and the first back surface;
wherein a length of the first front surface along a first direction is a_1, a length of the first back surface along the first direction is b_1, an angle between the first outer lateral surface and the first back surface is θ_1, and the following conditions are satisfied:
$$0 < a\_ 1 / b\_ 1 \leq 0.6 ; and$$
$$25 degrees \leq θ \_ 1 \leq 65 degrees .$$

2. The optical sensing structure according to claim 1, wherein the first reflector further has a first inner lateral surface recessed from the first back surface towards the first front surface, and the first inner lateral surface surrounds the optical sensing element.

3. The optical sensing structure according to claim 1, further comprising an extending reflector, wherein the first back surface is located between the first front surface and the optical sensing element, the extending reflector is protruded from the first back surface of the at least one first reflector, and the extending reflector and the first back surface surround the optical sensing element.

4. The optical sensing structure according to claim 3, wherein a quantity of the at least one first reflector is plural, the first reflectors are arranged side by side, and the first back surfaces of the first reflectors are located between the first front surface and the optical sensing element.

5. The optical sensing structure according to claim 1, further comprising a first light guide disposed over the optical sensing element or between the optical sensing element and the at least one first reflector, wherein the at least one first reflector is disposed over the first light guide and located at a side of the optical sensing element, the first back surface is located between the first front surface and the sensing surface, and the first light guide is translucent.

6. The optical sensing structure according to claim 5, wherein an area of the first back surface is greater than or equal to an area of the sensing surface.

7. An optical sensing film, comprising:
a transparent substrate, having a supporting surface;
an optical sensing array, disposed to the transparent substrate or on the supporting surface of the transparent substrate, wherein the optical sensing array comprises a plurality of optical sensing structures, and each of the plurality of optical sensing structures comprises:
an optical sensing element, disposed on the supporting surface of the transparent substrate, wherein the optical sensing element has a sensing surface, and the sensing surface faces away from the supporting surface and is configured to sense ambient light intensity; and
at least one first reflector, located at a side of the optical sensing element, wherein the at least one first reflector has a first front surface, a first back surface and a first outer lateral surface, the first front surface is located over the sensing surface, the first back surface faces away from the first front surface, and the first outer lateral surface is located between the first front surface and the first back surface; and
at least one wire, disposed to the transparent substrate and electrically connected to the optical sensing elements;
wherein a length of the first front surface along a first direction is a_1, a length of the first back surface along the first direction is b_1, an angle between the first outer lateral surface and the first back surface is θ_1, and the following conditions are satisfied:
$$0 < a\_ 1 / b\_ 1 \leq 0.6 ; and$$
$$25 degrees \leq θ \_ 1 \leq 65 degrees .$$

8. The optical sensing film according to claim 7, wherein the at least one first reflector further has a first inner lateral surface recessed from the first back surface towards the first front surface, and the first inner lateral surface and the supporting surface surround the optical sensing element.

9. The optical sensing film according to claim 7, wherein the first back surface is located between the first front surface and the sensing surface, each of the plurality of optical sensing structures further comprises an extending reflector, the extending reflector is connected to and located between the first back surface and the supporting surface, and the extending reflector, the first back surface and the supporting surface surround the optical sensing element.

10. The optical sensing film according to claim 9, wherein a quantity of the at least one first reflector is plural, the first reflectors are arranged side by side, and the first back surfaces of the first reflectors are located between the first front surface and the optical sensing element.

11. The optical sensing film according to claim 7, wherein each of the plurality of optical sensing structures further comprises a first light guide disposed over the optical sensing element or between the optical sensing elements and the at least one first reflector, the at least one first reflector is disposed over the first light guide and located at a side of the optical sensing element away from the supporting surface, the first back surface is located between the first front surface and the sensing surface, and the first light guide is translucent.

12. The optical sensing film according to claim 11, wherein an area of the first back surface is greater than or equal to an area of the sensing surface.

13. The optical sensing film according to claim 7, wherein a width of a side of the at least one wire along a normal direction of the supporting surface is a_w, a width of another side of the at least one wire along the normal direction of the supporting surface is b_w, an angle of a lateral surface of the at least one wire with respect to the supporting surface is θ_w, and the following conditions are satisfied:
$$0 < a\_w / b\_w \leq 0.6 ; and$$
$$25 degrees \leq θ \_w \leq 65 degrees .$$

14. The optical sensing film according to claim 7, further comprising at least one second reflector disposed at a side of the at least one wire, wherein the at least one second reflector has a second front surface, a second back surface and a second outer lateral surface, the second front surface is located at a side of the at least one second reflector away from the supporting surface, the second back surface faces away from the second front surface, and the second outer lateral surface is located between the second front surface and the second back surface;
wherein a length of the second front surface along a second direction is a_2, a length of the second back surface along the second direction is b_2, an angle between the second outer lateral surface and the second back surface is θ_2, and the following conditions are satisfied:
$$0 < a\_ 2 / b\_ 2 \leq 0.6 ; and$$
$$25 degrees \leq θ \_ 2 \leq 65 degrees .$$

15. The optical sensing film according to claim 14, wherein the at least one second reflector further has a second inner lateral surface recessed from the second back surface towards the second front surface, and the second inner lateral surface faces towards the at least one wire.

16. The optical sensing film according to claim 14, further comprising at least one second light guide disposed on the supporting surface, wherein the at least one second reflector is disposed over the at least one second light guide and located at a side of the at least one wire, the second back surface is located between the second front surface and the at least one wire, and the at least one second light guide is translucent.

17. The optical sensing film according to claim 7, wherein the at least one wire is located on the supporting surface of the transparent substrate or located in the transparent substrate.

18. The optical sensing film according to claim 7, further comprising:
at least one layer structure, being translucent and disposed at a side of the plurality of optical sensing structures away from the transparent substrate; and
an adhesion layer, being translucent and disposed at a side of the transparent substrate where the at least one layer structure is not disposed.

19. The optical sensing film according to claim 18, further comprising:
at least one reflection structure, disposed on the supporting surface of the transparent substrate;
wherein a length of a side of the at least one reflection structure away from the transparent substrate along the first direction is a_r, a length of a side of the at least one reflection structure close to the transparent substrate along the first direction is b_r, an angle of a lateral surface of the at least one reflection structure with respect to the supporting surface is θ_r, and the following conditions are satisfied:
$$0 < a\_r / b\_r \leq 0.6 ; and$$
$$25 degrees \leq θ \_r \leq 65 degrees .$$

20. An optical display system, comprising:
the optical sensing film of claim 7;
a projector, facing towards the optical sensing film; and
a controller, in communication connection with the at least one wire and the projector, wherein the controller is configured to obtain a plurality of intensity values of ambient light sensed by the optical sensing array, and the controller is configured to adjust optical characteristics of projection light emitted from the projector based on the plurality of intensity values.
